(19) United States
(12) Patent Application Publication
(10) Pub. No.: US 2024/0172418 A1
(43) Pub. Date: May 23, 2024

(54) SEMICONDUCTOR STRUCTURE AND FORMING METHOD THEREFOR

(71) Applicant: ICLEAGUE TECHNOLOGY CO., LTD., Jiaxing, Zhejiang (CN)

(72) Inventors: Wenyu HUA, Jiaxing, Zhejiang (CN); Boyong HE, Jiaxing, Zhejiang (CN)

(73) Assignee: ICLEAGUE TECHNOLOGY CO., LTD., Jiaxing, Zhejiang (CN)

(21) Appl. No.: 18/552,391

(22) PCT Filed: Jan. 10, 2022
(86) PCT No.: PCT/CN2022/070972

§ 371 Date: Sep. 25, 2023

(30) Foreign Application Priority Data
Apr. 7, 2021 (CN) 202110374510.5

(51) Int. Cl. H10B 12/00

(52) U.S. Cl. CPC H10B 12/33; H10B 12/036; H10B 12/053

(57) ABSTRACT

A semiconductor structure and a forming method therefor. The forming method comprises: providing a first substrate, which has opposite first and second faces, and comprises several discrete active regions arranged in a first direction and parallel to a second direction that is perpendicular to the first direction, wherein the first face exposes an isolation layer disposed between adjacent active regions; forming in the first substrate several first recesses, which extend from the first face to the second face, are arranged in the second direction, and penetrates the active regions in the first direction, and have a bottom with a distance less than the thickness of the isolation layer from the first face; forming word line gate structures within the first recesses; thinning the first substrate from the second face; and forming on the second face bit lines, wherein one active region and one bit line are electrically interconnected.

### CROSS-REFERENCE TO RELATED APPLICATIONS

This application claims the benefit of priority to Chinese Patent Application No. 202110374510.5, filed on Apr. 7, 2021 with China National Intellectual Property Administration, and entitled “SEMICONDUCTOR STRUCTURE AND FORMING METHOD THEREFOR”, the entire disclosure of which is incorporated herein by reference.

### TECHNICAL FIELD

The present disclosure relates to the field of semiconductor manufacturing, and particularly, to a semiconductor structure and a method for forming the same.

### BACKGROUND

Today, with rapid development of science and technology, semiconductor memories are widely applied in electronic devices. Among them, dynamic random access memory (DRAM), a type of volatile memory, is the most commonly used solution for applications that store large amounts of data.

Memories typically includes a storage capacitor and a storage transistor coupled with the storage capacitor. The storage capacitor is used for storing charges representing stored information. The storage transistor, a switch for controlling flow and discharge of charges into and from the storage capacitor, is also coupled to an internal circuit in the memory to receive a control signal from the internal circuit. Here, the storage transistor has a source region, a drain region, and a gate formed therein. And, the gate is used to control the current flow between the source region and the drain region, and is coupled to a word line. The drain region is used to form a bit line contact region to couple to a bit line. The source region is used to form a storage node contact region to couple to the storage capacitor.

The development of dynamic random access memory has required higher stability in a formation process therefor. A bit line is generally formed using photolithography, during which bit lines are required to be aligned with a bit line contact, and thus, a relatively high requirement is needed for the alignment process in photolithography, which increases difficulty in manufacturing process.

Therefore, the existing process window for forming a bit line is relatively small, it is hard to form a memory with high stability in performance, and the existing process for forming a bit line needs to be further improved.

### SUMMARY

The present disclosure provides a semiconductor structure and a method for forming the same to improve the process window for forming a bit line and stability in performance of the memory.

Embodiments of the present disclosure provides a semiconductor structure, which includes a first substrate, which has a first surface and a second surface opposite to the first surface, and includes several discrete active areas arranged in a first direction and parallel to a second direction, wherein the first direction is perpendicular to the second direction, an isolation layer is disposed between adjacent active areas, and the first surface and the second surface expose the isolation layer; a plurality of first grooves, which are disposed in the first substrate, extend from the first surface to the second surface, are arranged in the second direction, and run through the active areas along the first direction, as well as have a bottom with a distance less than the thickness of the isolation layer from the first surface; a word line gate structure, which is disposed in the first grooves; a plurality of bit lines, which are disposed on the second surface, arranged in the first direction, and parallel to the second direction, wherein one of the active areas is electrically coupled with one of the bit lines.

Optionally, the isolation layers have a surface protruding from the second surface, and have a second groove between each other, wherein the second groove exposes the second surface, is parallel to the second direction, and is arranged in the first direction; and the bit lines are disposed in the second groove.

Optionally, the semiconductor structure further includes a dielectric layer, which is disposed on the second surface and has a second groove exposing a surface of the active areas therein, wherein the second groove is parallel to the second direction and arranged in the first direction; and the bit lines are disposed in the second groove.

Optionally, the semiconductor structure further includes a plurality of second source/drain regions, which are disposed in each of the active areas, and extend from the first surface to the second surface.

Optionally, the semiconductor structure further includes a plurality of capacitors, which are disposed on the first surface, and each of which is electrically coupled with one of the second source/drain regions.

Optionally, the semiconductor structure further includes a first source/drain region, which is disposed in the active areas, and extends from a bottom of the second groove to the first surface.

Correspondingly, the embodiments of the present disclosure further provide a method for forming the aforementioned semiconductor structure, which includes providing a first substrate, which has a first surface and a second surface opposite to the first surface, and includes several discrete active areas arranged in a first direction and parallel to a second direction, wherein the first direction is perpendicular to the second direction, an isolation layer is disposed between adjacent active areas, and the first surface exposes the isolation layer; forming in the first substrate a plurality of first grooves, which extend from the first surface to the second surface, are arranged in the second direction, and run through the active areas along the first direction, as well as have a bottom with a distance less than the thickness of the isolation layer from the first surface; forming a word line gate structure in the first grooves; thinning the first substrate from the second surface, until a surface of the isolation layer is exposed; and after the thinning, forming on the second surface a plurality of bit lines, which are arranged in the first direction, and parallel to the second direction, wherein one of the active areas is electrically coupled with one of the bit lines.

Optionally, a method for forming the bit lines includes after the thinning, etching the first substrate from the second surface to form a second groove between adjacent isolation layers; and forming the bit lines in the second groove.

Optionally, after forming the second groove and before forming the bit lines, the method further includes forming in the active areas a first source/drain region, which has a first doped ion therein, and extends from a bottom of the second groove to the first surface.

Optionally, a method for forming the first source/drain region includes implanting into the active areas at the bottom of the second groove a first doped ion, which includes an N-type ion or a P-type ion; and annealing the first substrate.

Optionally, the bit lines include an electrode layer, and a method for forming the bit lines includes depositing an electrode material layer from the second surface to the surface of the isolation layer and in the second groove; and planarizing the electrode material layer, until the surface of the isolation layer is exposed.

Optionally, the bit lines further include a barrier layer between the electrode layer and the second groove.

Optionally, after forming the second groove and before forming the bit lines, the method further includes performing a surface treatment on the second groove, so as to form a contact layer on a surface of the second groove.

Optionally, the contact layer is made of a material including a metal silicide.

Optionally, after forming the word line gate structure, the method further includes implanting from the first surface into the active areas a second doped ion, which includes an N-type ion or a P-type ion, and has a conductivity type same as the conductivity type of the first doped ion, so as to form a plurality of second source/drain regions on each of the active areas.

Optionally, after forming the second source/drain regions and before the thinning, the method further includes forming on the first surface a plurality of capacitors, each of which is electrically coupled with one of the second source/drain regions.

Optionally, the word line gate structure includes a first side wall and a second side wall opposite in the second direction, and after forming the word line gate structure and before forming the capacitors, the method further includes forming between each of the active areas and the adjacent first side wall an insulation trench, which extends from the first surface to the second surface, and runs through the active areas along the first direction; and forming an insulation layer in the insulation trench.

Optionally, after forming the second source/drain regions and before forming the capacitors, the method further includes forming on the first surface a capacitor contact, through which the capacitors are electrically coupled with the second source/drain regions.

Optionally, the bit lines are made of a material including a metal.

Optional, the method further includes providing a second substrate; and after forming the isolation layer and before the thinning, bonding the first substrate and the second substrate with the first surface facing the second substrate.

Optionally, a method for forming the bit lines includes forming a dielectric material layer on the second surface after the thinning; forming on a surface of the dielectric material layer a first patterned layer, which exposes the dielectric material layer on the active areas; etching the dielectric material layer with the first patterned layer as a mask, until a surface of the active areas is exposed, so as to form a dielectric layer and a second groove disposed in the dielectric layer; and forming the bit lines in the second groove.

Optionally, the word line gate structure includes a gate dielectric layer disposed on side wall and bottom surfaces of the first grooves, as well as a gate layer disposed on the gate dielectric layer.

Optionally, the gate layer is made of a material including a metal, and the gate dielectric layer is made of a material including an oxide.

Optionally, a method for forming the first grooves includes forming on the first surface a second patterned layer, which exposes surfaces of part of the active areas and part of the isolation layer; and etching the active areas and the isolation layer with the second patterned layer as a mask.

The embodiments of the present disclosure have the following beneficial effects.

In the method for forming a semiconductor structure according to the embodiments of the present disclosure, the word line gate structure is formed in the first grooves, and the first substrate is thinned from the second surface until the surface of the isolation layer is exposed. In addition, after the thinning, the bit lines arranged in the first direction and parallel to the second direction are formed on the second surface, and one of the active areas is electrically coupled with one of the bit lines. Thus, the bit lines are in direct contact with the active areas, without preparing a bit line contact. Therefore, in preparation of the bit lines, the bit lines are not required to be aligned with the bit line contact. Thereby, reducing difficulty in manufacturing process, improving the process window for forming the bit lines, and saving production costs.

Furthermore, the bit lines are formed without photolithography, but rather adopting a self-aligning method which defines a position of the bit lines using the position of the isolation layer, and thereby, saving the use of the mask, and reducing costs of the manufacturing process.

### BRIEF DESCRIPTION OF THE DRAWINGS

FIGS. 1 to 18 are schematic intermediate structure diagrams of a method for forming a semiconductor structure according to an embodiment of the present disclosure.

### DETAILED DESCRIPTION

It should be noted that, the terms “surface” and “on” in this disclosure are used to describe relative positional relationships in space and are not limited to direct contact.

As described in the BACKGROUND, the existing process window for forming a bit line is relatively small, it is hard to form memory with high stability in performance, and the existing process for forming a bit line needs to be further improved.

The present disclosure provides a method for forming a semiconductor structure, in which the word line gate structure is formed in the first grooves, and the first substrate is thinned from the second surface until the surface of the isolation layer is exposed. In addition, after the thinning, the bit lines arranged in the first direction and parallel to the second direction are formed on the second surface, and one of the active areas is electrically coupled with one of the bit lines. Thus, the bit lines are in direct contact with the active areas, without preparing a bit line contact. Therefore, in preparation of the bit lines, the bit lines are not required to be aligned with the bit line contact. Thereby, reducing difficulty in manufacturing process, improving the process window for forming the bit lines, and saving production costs.

In order to make the above purposes, features, and beneficial effects of the present disclosure more apparent and understandable, specific embodiments of the present disclosure will be explained in detail below in conjunction with the accompanying drawings.

FIGS. 1 to 18 are schematic intermediate structure diagrams of a method for forming a semiconductor structure according to an embodiment of the present disclosure.

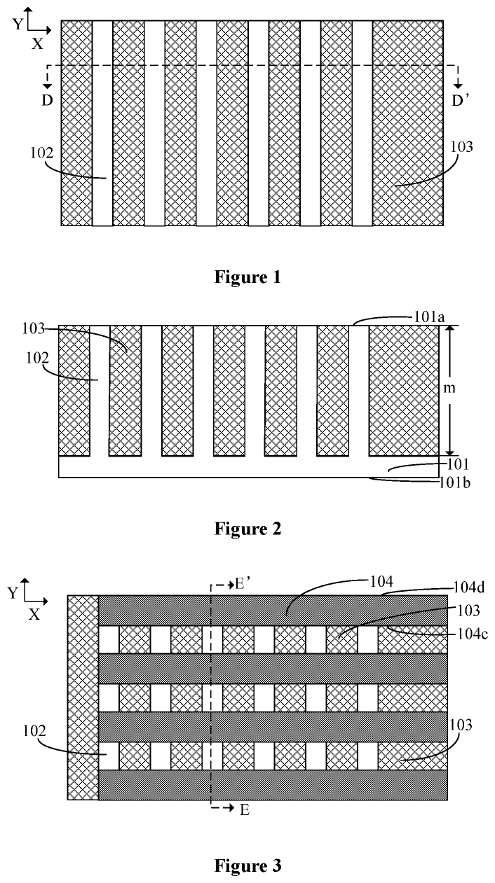

Please refer to FIGS. 1 and 2, wherein FIG. 1 is a schematic top view, and FIG. 2 is a schematic sectional view along the DD′ direction in FIG. 1. A first substrate 101 is provided, which has a first surface 101a and a second surface 101b opposite to the first surface 101a, and includes several discrete active areas 102 arranged in a first direction X and parallel to a second direction Y. The first direction X is perpendicular to the second direction Y. And, an isolation layer 103 is disposed between adjacent active areas 102. Additionally, and the first surface 101a exposes the isolation layer 103.

In this embodiment, the first substrate 101 is made of silicon. According to other embodiments, the first substrate may be made of a material including silicon carbide, silicon-germanium, multicomponent semiconductor materials composed of III-V group elements, silicon on insulator (SOI), or germanium on insulator. Here, the multicomponent semiconductor materials composed of III-V group elements may include InP, GaAs, GaP, InAs, InSb, InGaAs, or InGaAsP.

The active areas 102 is used to form a source/drain region and a channel region of a device.

A process for forming the isolation layer 103 may include chemical vapor deposition processes. The isolation layer 103 is used for electrical insulation between different electric devices.

The isolation layer 103 has a thickness of m, which refers to the size of the isolation layer 103 in a direction perpendicular to a surface of the first substrate 101.

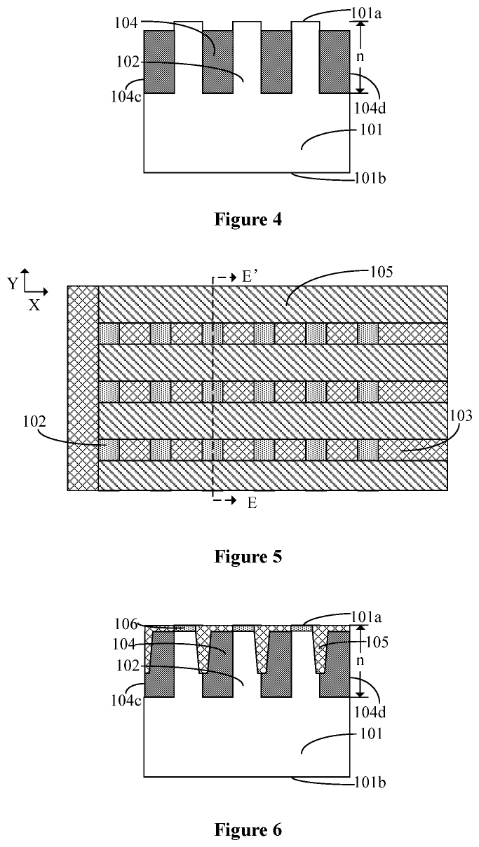

Please refer to FIGS. 3 and 4, wherein FIG. 3 is a schematic top view, and FIG. 4 is a schematic sectional view along the EE′ direction in FIG. 3. A plurality of first grooves (not shown) are formed in the first substrate 101. The plurality of first grooves extend from the first surface 101a to the second surface 101b, are arranged in the second direction Y, and run through the active areas 102 along the first direction X, as well as have a bottom with a distance n less than the thickness m of the isolation layer 103 from the first surface 101a. And, a word line gate structure 104 is formed in the first grooves.

In this embodiment, the isolation layer 103 is subsequently further used to define a position of the bit lines.

A method for forming the first grooves may include forming on the first surface 101a a second patterned layer (not shown), which exposes surfaces of part of the active areas 102 and part of the isolation layer 103; and etching the active areas 102 and the isolation layer 103 with the second patterned layer as a mask.

The word line gate structure 104 may include a gate dielectric layer (not shown) disposed on side wall and bottom surfaces of the first grooves, as well as a gate layer (not shown) disposed on the gate dielectric layer.

The gate layer may be made of a material including a metal, and the gate dielectric layer may be made of a material including an oxide.

The word line gate structure 104 may include a first side wall 104c and a second side wall 104d opposite in the second direction Y.

In this embodiment, the word line gate structure 104 has a top surface lower than the top surface of the active areas 102, which provides physical space for subsequently implanting a second doped ion from the first surface 101a into the active areas 102, so as to form a plurality of second source/drain regions.

Subsequently, after the word line gate structure is formed, the plurality of second source/drain regions are further formed on each of the active areas 102; the first substrate 101 is thinned from the second surface 101b, until the surface of the isolation layer 103 is exposed; and after the second source/drain regions are formed and before the first substrate 101 is thinned, a plurality of capacitors are further formed on the first surface 101a, and each of the capacitors is electrically coupled with one of the second source/drain regions. In this embodiment, after the word line gate structure 104 is formed and before the capacitors are formed, an insulation layer is further formed between each of the active areas 102 and the adjacent first side wall 104c. A method for forming the insulation layer is shown in FIGS. 5 to 6.

Please refer to FIGS. 5 to 6, wherein FIG. 5 is a schematic top view, and FIG. 6 is a schematic sectional view along the EE′ direction in FIG. 5. An insulation trench (not shown) is formed between each of the active areas 102 and the adjacent first side wall 104c. The insulation trench extends from the first surface 101a to the second surface 101b, and runs through the active areas 102 along the first direction X. And, an insulation layer 105 is formed in the insulation trench.

A process for forming the insulation trench may include dry etching processes, which is conducive to forming relatively good morphology for insulation trench.

In this embodiment, the insulation trench is also disposed partially in the word line gate structure 104.

In this embodiment, the insulation trench has a bottom lower than half of the height of the word line gate structure 104, which may ensure the isolation effect of the insulation layer 105, avoid the control effect of the word line gate structure 104 on the active areas 102 channel adjacent to the first side wall 104c, and reduce leakage current.

In this embodiment, the insulation layer 105 is also disposed on the top surface of the word line gate structure 104.

The insulation layer 105 is disposed between the second side wall 104c of the word line gate structure 104 and the active areas 102. In addition, the second side wall 104d of the word line gate structure 104 is adjacent to the active areas 102. Thus, the insulation layer 105 is capable of isolating the first side wall 104c and the active areas 102, avoiding the simultaneous contact between the word line gate structure 104 and the adjacent active areas 102 on two sides to generate two parasitic devices formed in channels to make it difficult for the transistor to turn off, thereby enabling to reduce leakage current.

A method for forming the insulation layer 105 may include forming a dielectric material layer (not shown) in the insulation trench, at the top of the word line gate structure 104, and on a surface of the active areas 102; and planarizing the dielectric material layer, until the surface of the active areas 102 is exposed.

The insulation layer 105 may be made of a material including a dielectric material, which includes a combination of one or more in silicon oxides, silicon nitrides, silicon carbides, silicon oxycarbides, silicon oxynitrides, aluminum oxides, aluminum nitrides, silicon carbonitrides, and silicon oxycarbonitrides.

In this embodiment, the insulation layer 105 may be made of a material including a silicon oxide.

Please continue to refer to FIGS. 5 and 6. After the word line gate structure 104 is formed, a second doped ion which may include an N-type ion or a P-type ion is further implanted into the active areas 102 from the first surface 101a, so as to form a plurality of second source/drain regions 106 on each of the active areas 102.

In this embodiment, the second doped ion is an N-type ion for forming an NMOS device. According to other embodiments, the second doped ion is a P-type ion for forming a PMOS device.

Subsequently, the first substrate 101 is thinned from the second surface 101b, until the surface of the isolation layer 103 is exposed. After the second source/drain regions 106 are formed, and before the first substrate 101 is thinned, the method may further include forming on the first surface 101a a plurality of capacitors, each of which is electrically coupled with one of the second source/drain regions 106.

In this embodiment, after the word line gate structure 104 is formed and before the capacitors are formed, the insulation layer 105 is formed. Specifically, the insulation layer 105 is formed before formation of the second source/drain regions 106. According to other embodiments, the insulation layer 105 may be formed before formation of the capacitors and after formation of the second source/drain regions 106.

Please refer to FIGS. 7 to 9 for a method for forming the capacitors.

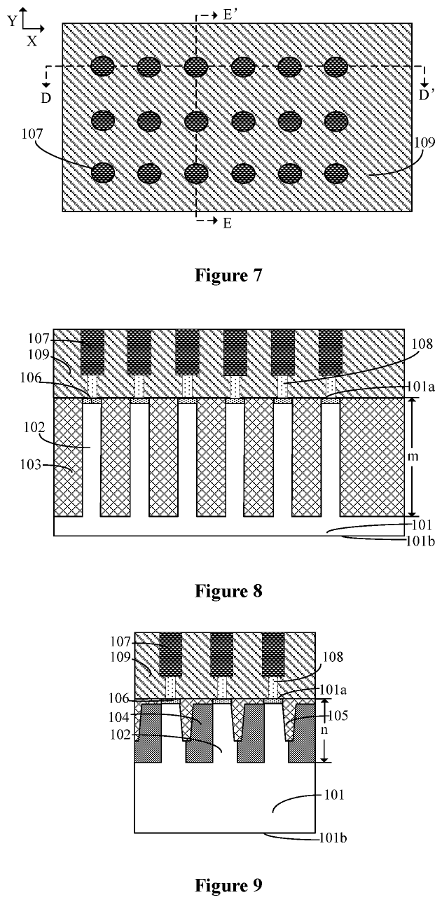

Please refer to FIGS. 7 to 9, wherein FIG. 7 is a schematic top view, FIG. 8 is a schematic sectional view along the DD′ direction in FIG. 7, and FIG. 9 is a schematic sectional view along the EE′ direction in FIG. 7. A plurality of capacitors 107 are formed on the first surface 101a. And, each of the capacitors 107 is electrically coupled with one of the second source/drain regions 106.

After the second source/drain regions 106 are formed, and before the capacitors 107 are formed, a capacitor contact 108 is formed on the first surface 101a. And, the capacitors 107 are electrically coupled with the second source/drain regions 106 through the capacitor contact 108.

In this embodiment, a dielectric material layer 109 is further formed on the first surface 101a. And, the capacitors 107 and the capacitor contact 108 are disposed in the dielectric material layer 109.

A method for forming the capacitor contact 108 and the capacitors 107 may include forming a third groove (not shown) in the dielectric material layer 109; forming in the third groove a fourth groove (not shown), which exposes a part of the surface of the second source/drain regions 106; and forming the capacitor contact 108 in the fourth groove, and forming the capacitors 107 in the third groove. The method for forming the capacitor contact 108 and the capacitors 107 has a relatively large process window and a relatively simple process, which enables to improve production efficiency.

The capacitors 107 may include a first electrode layer (not shown), a second electrode layer (not shown), and a dielectric layer (not shown) disposed between the first electrode layer and the second electrode layer.

Shape of the dielectric layer may include a planar shape or a “U” shape.

When the shape of the dielectric layer is planar, surfaces of the first electrode layer and the second electrode layer are completely flat.

When the shape of the dielectric layer is “U” shaped, surfaces of the first electrode layer and the second electrode layer are uneven surfaces; alternatively, surfaces of the first electrode layer and the second electrode layer are completely flat.

Materials of the first electrode layer and the second electrode layer may each independently include a metal or a metal nitride. The metal may include a combination of one or more in copper, aluminum, tungsten, cobalt, nickel, and tantalum. The metal nitride may include a combination of one or more in tantalum nitride and titanium nitride.

The capacitor contact 108 may be made of a material including a metal or a metal nitride. The metal may include a combination of one or more in copper, aluminum, tungsten, cobalt, nickel, and tantalum. The metal nitride may include a combination of one or more in tantalum nitride and titanium nitride.

According to another embodiment, the capacitor 107 is electrically coupled to and in direct contact with the second source/drain regions 106, without forming the capacitor contact 108.

In this embodiment, a second substrate is further provided. Additionally, after the isolation layer 103 is formed and before the first substrate 101 is thinned, the first substrate 101 and the second substrate are bonded with the first surface 101a facing the second substrate.

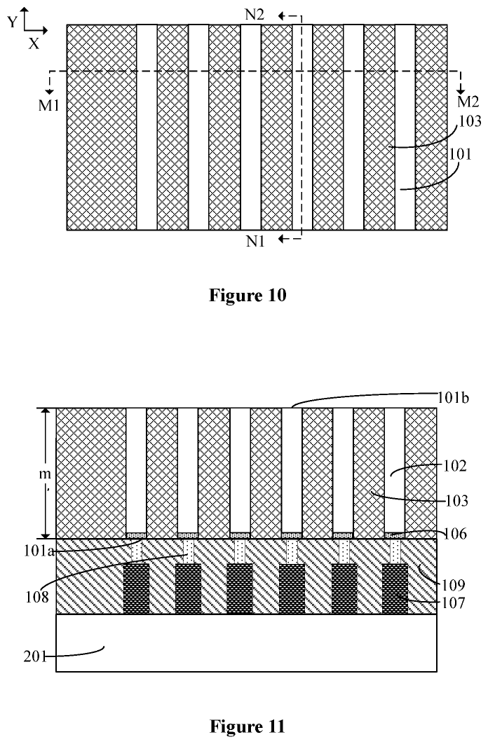

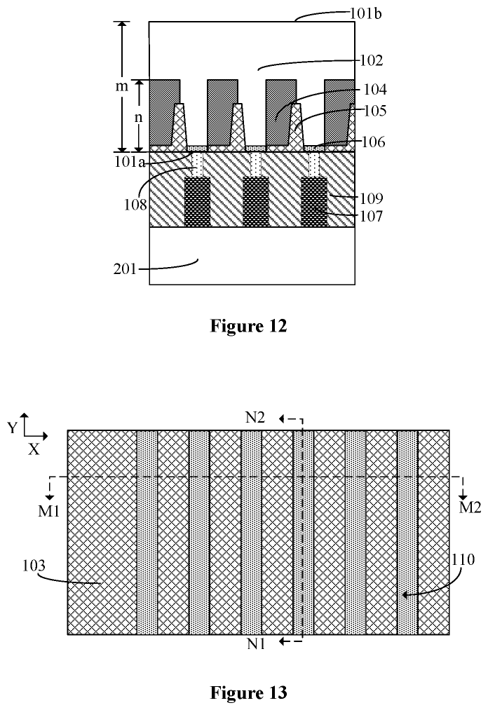

Please refer to FIGS. 10 to 12, wherein FIG. 10 is a schematic top view, FIG. 11 is a schematic sectional view along the M1M2 direction in FIG. 10, and FIG. 12 is a schematic sectional view along the NIN2 direction in FIG. 10. A second substrate 201 is provided. Then, the first substrate 101 and the second substrate 201 are bonded with the first surface 101a facing the second substrate 201. Thereafter, the first substrate 101 is thinned from the second surface 101b, until the surface of the isolation layer 103 is exposed.

The second substrate 201 is made of silicon. According to other embodiments, the second substrate may be made of a material including silicon carbide, silicon germanium, multicomponent semiconductor materials composed of III-V group elements, silicon on insulator (SOI), or germanium on insulator. Here, the multicomponent semiconductor materials composed of III-V group elements may include InP, GaAs, GaP, InAs, InSb, InGaAs, or InGaAsP.

Specifically, after the capacitor 107 is formed, the first substrate 101 and the second substrate 201 are bonded.

In this embodiment, after the first substrate 101 and the second substrate 201 are bonded, the first surface 101a and the second surface 101b of the first substrate 101 are further inverted, that is, the second substrate 201 is disposed below the first substrate 101, to be used as a base for subsequent operations.

A process for thinning may include chemical mechanical polish processes.

Subsequently, after the first substrate 101 is thinned, a plurality of bit lines are formed on the second surface 101b. The bit lines are arranged in the first direction X, and parallel to the second direction Y. And, one of the active areas 102 is electrically coupled with one of the bit lines. According to the method, a memory structure may be formed, which has the capacitor 107 and bit lines disposed on two sides of the transistor (active areas 102). The memory structure is different from a memory in which a bit line and a capacitor are disposed on the same side above the transistor, and a contact line of the capacitor must pass through without contacting the bit line, enabling to effectively reduce an area occupied by the memory, and increase the integration level of the memory.

In this embodiment, please refer to FIGS. 13 to 18 for a method for forming the bit lines.

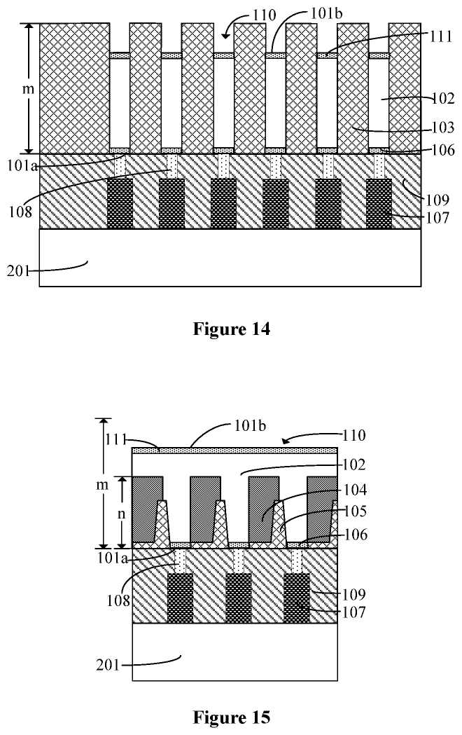

Please refer to FIGS. 13 to 15, wherein FIG. 13 is a schematic top view, FIG. 14 is a schematic sectional view along the M1M2 direction in FIG. 13, and FIG. 15 is a schematic sectional view along the NIN2 direction in FIG. 13. After the first substrate 101 is thinned, the first substrate 101 is etched from the second surface 101b, so as to form a second groove 110 between adjacent isolation layers 103.

In this embodiment, after the second groove 110 is formed and before the bit lines are formed, a first source/drain region 111 is further formed in the active areas 102. The first source/drain region 111 has a first doped ion therein, and extends from the bottom of the second groove 110 to the first surface 101a. And, the first doped ion has a conductivity type same as the conductivity type of the second doped ion.

A method for forming the first source/drain region 111 may include implanting into the active areas 102 at the bottom of the second groove 110 a first doped ion, which may include an N-type ion or a P-type ion; and annealing the first substrate 101.

A channel region of the device is formed between the first source/drain region 111 and the second source/drain regions 106. A vertical channel device structure is formed in the channel region in a direction perpendicular to the surface of the first substrate 101.

In this embodiment, the first doped ion is an N-type ion for forming an NMOS device. According to other embodiments, the first doped ion is a P-type ion for forming a PMOS device.

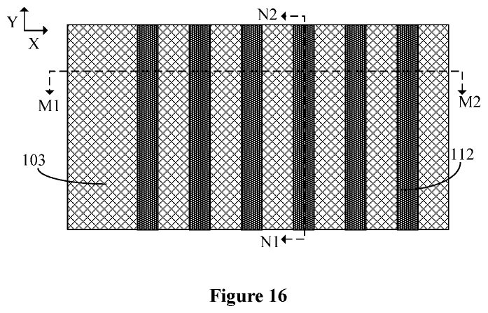

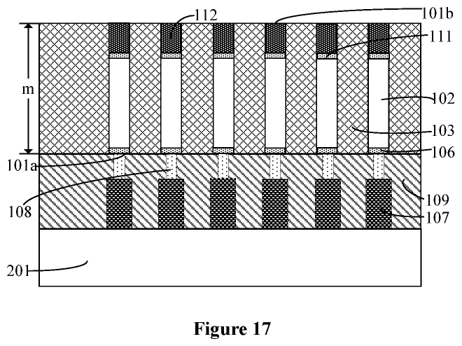

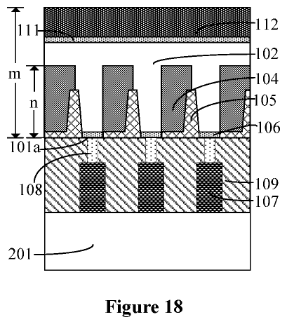

Please refer to FIGS. 16 to 18, wherein FIG. 16 is a schematic top view, FIG. 17 is a schematic sectional view along the M1M2 direction in FIG. 16, and FIG. 18 is a schematic sectional view along the NIN2 direction in FIG. 16. A bit line 112 is formed in the second groove 110.

The bit line 112 includes an electrode layer (not shown).

The bit line 112 may be made of a material including a metal. In this embodiment, the metal is copper. According to other embodiments, the metal may be tungsten, aluminum, and the like.

The bit line 112 is in direct contact with the active areas 102, without preparing a bit line contact. Thus, during bit line preparation, the bit line does not required to be aligned with the bit line contact, reducing difficulty in manufacturing process, improving the process window for forming the bit line, and saving production costs.

In this embodiment, the position of the bit line 112 is defined by the isolation layer 103, and the bit line 112 is formed using a self-aligning method. Therefore, the formation process of the bit line 112 does not require the photolithography, and thereby saving the use of photomask and reducing manufacturing process costs.

A method for forming the bit line 112 may include depositing an electrode material layer (not shown) from the second surface 101b to the surface of the isolation layer 103 and in the second groove 110; and planarizing the electrode material layer, until the surface of the isolation layer 103 is exposed.

The bit line 112 further includes a barrier layer (not shown) between the electrode layer and the second groove 110. The barrier layer is used to block diffusion of ions in the active areas 102 towards the electrode layer, which is conducive to improving stability in performance of the device.

In this embodiment, after the second groove 110 is formed and before the bit line 112 is formed, a surface treatment is further performed on the second groove 110 to form a contact layer (not shown) on a surface of the second groove 110.

A process for forming the contact layer may include self-aligning metal silicification processes.

The contact layer may be made of a material including a metal silicide. In this embodiment, the metal silicide is titanium silicide. The contact layer is used to reduce the contact resistance between the bit line 112 and the active areas 102.

According to other embodiments, the method for forming the bit line may include forming a dielectric material layer on the second surface after the first substrate 101 is thinned; forming on a surface of the dielectric material layer a first patterned layer, which exposes the dielectric material layer on the active areas; etching the dielectric material layer with the first patterned layer as a mask, until the surface of the active areas is exposed, so as to form a dielectric layer and a second groove disposed in the dielectric layer; and forming the bit line in the second groove. The bit line is in direct contact with the active areas, without preparing a bit line contact. Thus, in preparation of the bit line, the bit line is not required to be aligned with the bit line contact, thereby reducing difficulty in manufacturing process, improving the process window for forming the bit line, and saving production costs.

Correspondingly, an embodiment of the present disclosure further provides a semiconductor structure formed by the above method. Please continue to refer to FIGS. 16 to 18, the semiconductor structure may include a first substrate 101, which has a first surface 101a and a second surface 101b opposite to the first surface 101a, and includes several discrete active areas 102 arranged in a first direction X and parallel to a second direction Y, wherein the first direction X is perpendicular to the second direction Y, an isolation layer 103 is disposed between adjacent active areas 102, and the first surface 101a and the second surface 101b expose the isolation layer 103; a plurality of first grooves (not shown), which are disposed in the first substrate 101, extend from the first surface 101a to the second surface 101b, are arranged in the second direction Y, and run through the active areas 102 along the first direction X, as well as have a bottom with a distance less than the thickness of the isolation layer 103 from the first surface 101a; a word line gate structure 104, which is disposed in the first grooves; a plurality of bit lines 112, which are disposed on the second surface 101b, arranged in the first direction X, and parallel to the second direction Y, wherein one of the active areas 102 is electrically coupled with one of the bit lines 112.

In this embodiment, the isolation layers 103 have a surface protruding from the second surface 101b, and have a second groove 110 between each other, wherein the second groove 110 exposes the second surface 101b, is parallel to the second direction Y, and is arranged in the first direction X; and the bit lines 112 are disposed in the second groove 110. On the one hand, the bit lines 112 are in direct contact with the active areas 102, without preparing a bit line contact. Thus, in preparation of the bit lines, the bit lines are not required to be aligned with the bit line contact, thereby reducing difficulty in manufacturing process, improving the process window for forming the bit lines, and saving production costs. On the other hand, the positions of the bit lines 112 are defined by the isolation layer 103, and the bit lines 112 are formed using a self-aligning method. Therefore, formation process of the bit lines 112 does not require the photolithography, and thereby saving the use of photomask and reducing manufacturing process costs.

According to other embodiments, the semiconductor structure further includes a dielectric layer, which is disposed on the second surface, and has a second groove exposing a surface of the active areas therein, wherein the second groove is parallel to the second direction and arranged in the first direction; and the bit lines are disposed in the second groove. The bit lines are in direct contact with the active areas, without preparing a bit line contact. Thus, in preparation of the bit lines, the bit lines are not required to be aligned with the bit line contact, thereby reducing difficulty in manufacturing process, improving the process window for forming the bit lines, and saving production costs.

In this embodiment, the semiconductor structure further includes a plurality of second source/drain regions 106, which are disposed in each of the active areas 102, extend from the first surface 101a to the second surface 101b.

In this embodiment, the semiconductor structure further includes a plurality of capacitors 107, which are disposed on the first surface 101a, and each of which is electrically coupled with one of the second source/drain regions 106.

In this embodiment, the semiconductor structure further includes a first source/drain region 111, which is disposed in the active areas 102, and extends from a bottom of the second groove 110 (as shown in FIG. 12) to the first surface 101a.

Although the present disclosure is disclosed as above, the present disclosure is not limited hereto. Any person skilled in the art may make various changes and modifications without departing from the spirit and scope of the present disclosure. Therefore, the scope of protection of the present disclosure shall be subject to the scope limited by the claims.

1. A semiconductor structure, comprising:
a first substrate, which has a first surface and a second surface opposite to the first surface, and comprises several discrete active areas arranged in a first direction and parallel to a second direction, wherein the first direction is perpendicular to the second direction, an isolation layer is disposed between adjacent active areas, and the first surface and the second surface expose the isolation layer;
a plurality of first grooves, which are disposed in the first substrate, extend from the first surface to the second surface, are arranged in the second direction, and run through the active areas along the first direction, as well as have a bottom with a distance less than the thickness of the isolation layer from the first surface;
a word line gate structure, which is disposed in the first grooves;
a plurality of bit lines, which are disposed on the second surface, arranged in the first direction, and parallel to the second direction, wherein one of the active areas is electrically coupled with one of the bit lines.

2. The semiconductor structure according to claim 1, wherein the isolation layers have a surface protruding from the second surface, and have a second groove between each other, wherein the second groove exposes the second surface, is parallel to the second direction, and is arranged in the first direction; and the bit lines are disposed in the second groove.

3. The semiconductor structure according to claim 1, further comprising a dielectric layer, which is disposed on the second surface and has a second groove exposing a surface of the active areas therein, wherein the second groove is parallel to the second direction and arranged in the first direction; and the bit lines are disposed in the second groove.

4. The semiconductor structure according to claim 1, further comprising a plurality of second source/drain regions, which are disposed in each of the active areas, and extend from the first surface to the second surface.

5. The semiconductor structure according to claim 4, further comprising a plurality of capacitors, which are disposed on the first surface, and each of which is electrically coupled with one of the second source/drain regions.

6. The semiconductor structure according to claim 2, further comprising a first source/drain region, which is disposed in the active areas, and extends from a bottom of the second groove to the first surface.

7. A method for forming a semiconductor structure, comprising:
providing a first substrate, which has a first surface and a second surface opposite to the first surface, and comprises several discrete active areas arranged in a first direction and parallel to a second direction, wherein the first direction is perpendicular to the second direction, an isolation layer is disposed between adjacent active areas, and the first surface exposes the isolation layer;
forming in the first substrate a plurality of first grooves, which extend from the first surface to the second surface, are arranged in the second direction, and run through the active areas along the first direction, as well as have a bottom with a distance less than the thickness of the isolation layer from the first surface;
forming a word line gate structure in the first grooves;
thinning the first substrate from the second surface, until a surface of the isolation layer is exposed; and
after the thinning, forming on the second surface a plurality of bit lines, which are arranged in the first direction, and parallel to the second direction, wherein one of the active areas is electrically coupled with one of the bit lines.

8. The method for forming a semiconductor structure according to claim 7, wherein a method for forming the bit lines comprises after the thinning, etching the first substrate from the second surface to form a second groove between adjacent isolation layers; and forming the bit lines in the second groove.

9. The method for forming a semiconductor structure according to claim 8, after forming the second groove and before forming the bit lines, further comprising forming in the active areas a first source/drain region, which has a first doped ion therein, and extends from a bottom of the second groove to the first surface.

10. The method for forming a semiconductor structure according to claim 9, wherein a method for forming the first source/drain region comprises implanting into the active areas at the bottom of the second groove a first doped ion, which comprises an N-type ion or a P-type ion; and annealing the first substrate.

11. The method for forming a semiconductor structure according to claim 8, wherein the bit lines comprise an electrode layer and a barrier layer between the electrode layer and the second groove, and a method for forming the bit lines comprises depositing an electrode material layer from the second surface to the surface of the isolation layer and in the second groove; and planarizing the electrode material layer, until the surface of the isolation layer is exposed.

12. (canceled)

13. The method for forming a semiconductor structure according to claim 8, after forming the second groove and before forming the bit lines, further comprising performing a surface treatment on the second groove, so as to form a contact layer on a surface of the second groove.

14. (canceled)

15. The method for forming a semiconductor structure according to claim 9, after forming the word line gate structure, further comprising implanting from the first surface into the active areas a second doped ion, which comprises an N-type ion or a P-type ion, and has a conductivity type same as the conductivity type of the first doped ion, so as to form a plurality of second source/drain regions on each of the active areas.

16. The method for forming a semiconductor structure according to claim 15, after forming the second source/drain regions and before the thinning, further comprising forming on the first surface a plurality of capacitors, each of which is electrically coupled with one of the second source/drain regions.

17. The method for forming a semiconductor structure according to claim 16, wherein the word line gate structure comprises a first side wall and a second side wall opposite in the second direction, and after forming the word line gate structure and before forming the capacitors, the method further comprises forming between each of the active areas and the adjacent first side wall an insulation trench, which extends from the first surface to the second surface, and runs through the active areas along the first direction; and forming an insulation layer in the insulation trench.

18. The method for forming a semiconductor structure according to claim 16, after forming the second source/drain regions and before forming the capacitors, further comprising forming on the first surface a capacitor contact, through which the capacitors are electrically coupled with the second source/drain regions.

19. (canceled)

20. The method for forming a semiconductor structure according to claim 7, further comprising providing a second substrate; and after forming the isolation layer and before the thinning, bonding the first substrate and the second substrate with the first surface facing the second substrate.

21. The method for forming a semiconductor structure according to claim 7, wherein a method for forming the bit lines comprises forming a dielectric material layer on the second surface after the thinning; forming on a surface of the dielectric material layer a first patterned layer, which exposes the dielectric material layer on the active areas; etching the dielectric material layer with the first patterned layer as a mask, until a surface of the active areas is exposed, so as to form a dielectric layer and a second groove disposed in the dielectric layer; and forming the bit lines in the second groove.

22. The method for forming a semiconductor structure according to claim 7, wherein the word line gate structure comprises a gate dielectric layer disposed on side wall and bottom surfaces of the first grooves, as well as a gate layer disposed on the gate dielectric layer.

23. (canceled)

24. The method for forming a semiconductor structure according to claim 7, wherein a method for forming the first grooves comprises forming on the first surface a second patterned layer, which exposes surfaces of part of the active areas and part of the isolation layer, and etching the active areas and the isolation layer with the second patterned layer as a mask.
